(19) United States
(12) Patent Application Publication
(10) Pub. No.: US 2011/0146774 A1
(43) Pub. Date: Jun. 23, 2011

(54) Solar Cell Having Quantum Dot Nanowire Array and the Fabrication Method Thereof

(75) Inventors: Kyung Joong Kim, Daejeon (KR); Woo Lee, Daejeon (KR)

(73) Assignee: KOREA RESEARCH INSTITUTE OF STANDARDS AND SCIENCE, Daejeon (KR)

(21) Appl. No.: 13/058,302

(22) PCT Filed: Nov. 10, 2008
(86) PCT No.: PCT/KR2008/006618

§ 371 Date: Feb. 9, 2011

(30) Foreign Application Priority Data
Aug. 11, 2008 (KR) 10-2008-0078416

(51) Int. Cl. H01L 31/0352; H01L 31/18

(52) U.S. Cl. 136/255; 438/94; 257/E31.033

(57) ABSTRACT

The present invention relates to a solar cell having quantum dot nanowire array and the fabrication method thereof. The solar cell according to the present invention includes quantum dot nanowire array with a heterostructure including matrix and semiconductor quantum dots, and p-type and n-type semiconductor and electrodes each contacting the quantum dot nanowires. With the solar cell according to the present invention, the band gap energy of the semiconductor quantum dot can be easily controlled, the semiconductor quantum dots having different sizes are provided in the quantum dot nanowire so that the photoelectric conversion can be performed in the wide spectrum from visible rays to infrared rays, the quantum dot is embedded in the high density quantum dot nanowire array so that light absorption can be maximized, and the quantum dot nanowire contact p-type and n-type semiconductor over a wide area, conduction efficiency of electrons and holes can be improved.

### TECHNICAL FIELD

The present invention relates to a solar cell having quantum dot nanowire array and the fabricating method thereof, and more particularly to a solar cell having quantum dot nanowire array in which semiconductor quantum dots are internally embedded, and the fabrication method thereof.

### BACKGROUND ART

Since the Kyoto protocol aiming at resulting carbon dioxide (CO₂) emission, which are thought to contribute the global warming, had been adopted as of December, 1997, studies on renewable and clean alternative energy sources such as solar energy, wind power, and water power, have been actively developed in order to reduce a great quantity of carbon dioxide (CO₂).

A photovoltaic device (solar cell), which is spotlighted as clean alternative energy, means a device to generate current-voltage using photovoltaic effects that a semiconductor absorbs light to generate electrons and holes.

An n-p diode of inorganic semiconductor material such as silicon or gallium arsenide (GaAs), whose stability and efficiency have been proved, has been mainly used, however, a high manufacturing cost thereof has been an obstacle in substantial utilization of a solar cell.

Although cheaper solar cells using dye-sensitized material and organic/polymeric material have been actively developed, the market share of them is very low to around 3% compared to the silicon based solar cells due to a very low efficiency and a short life span by deterioration.

Although most of the photovoltaic devices use single crystal silicon and poly crystal silicon, the cost occupied by silicon material and wafer to construct a solar system exceeds 40% of the entire construction cost, and thus, there have been efforts to reduce the amount of silicon required in producing unit power through structural (morphology) or physical (bandgap engineering) approach and to minimize silicon consumption through a thin film device.

### DISCLOSURE

### Technical Problem

The object of the present invention is to provide a solar cell capable of performing a photoelectric conversion in a wide spectrum from visible to infrared lights, maximizing light absorption through bandgap engineering of material, and improving conductive efficiency of electrons and holes generated by absorbing light. Another object of the present invention is to provide a simple and economic fabricating method of a high efficiency solar cell with controllable band gap energy and a light absorbing layer where a photoelectric conversion is performed has a large specific surface area

### Technical Solution

To achieve the above object, the present invention provides a fabrication method of a solar cell having quantum dot nanowire array comprising:

a) fabricating a multilayer by repeatedly stacking matrix layers formed of semiconductor nitride or semiconductor oxide, and semiconductor layers on an upper part of a semiconductor substrate doped with p-type or n-type impurities; b) fabricating a quantum dot nanowire array constituted by a plurality of quantum dot nanowires whose one ends are fixed on the semiconductor substrate and are spaced from each other to be vertically arranged by partially etching the multilayer vertically to the semiconductor substrate and; c) depositing a semiconductor doped with the opposite-type impurities to impurities of the semiconductor substrate on the upper part of the semiconductor substrate formed with the quantum dot nanowire array and filling at least empty spaces between the other ends of the quantum dot nanowires and the semiconductor substrate with the semiconductor doped with opposite-type impurities; and d) forming a lower electrode on a lower part of the semiconductor substrate, and forming a upper electrode on a upper part surface formed with the quantum dot nanowire array and semiconductor surface doped with the opposite-type impurities or on an upper part of semiconductor surface doped with the opposite-type impurities so that the upper electrode corresponds to the lower electrode.

The fabrication method of a solar cell having quantum dot nanowire array in particular comprising: a) fabricating a multilayer film with alternating silicon nitride (or silicon oxide) layers and semiconductor layers on a semiconductor substrate doped with p-type or n-type impurities; b) fabricating a quantum dot nanowire array whose one ends are fixed on the semiconductor substrate and are spaced from each other to be vertically arranged by partial etching the a multiple stacked layers vertically to the semiconductor substrate and; c) filling the empty spaces between the other ends of the quantum dot nanowires and the semiconductor substrate with the semiconductor doped with opposite-type impurities; and d) forming a lower electrode on a lower part of the semiconductor substrate, and forming a upper electrode on a upper part surface formed with the quantum dot nanowire array.

The multilayer of a) step may be fabricated through a deposition process using a PVD or a CVD, the semiconductor layer and the matrix layer constituting the multilayer may have thickness less than 10 nm, independently from each other, the plurality of semiconductor layers constituting the multilayer may have different thickness, and the thickness of the respective semiconductor layers may be less than 10 nm, independently from each other.

The step b) may comprise: b1-1) depositing Ag, Au or a catalyst metal that is a transition metal on the upper part of the multilayer in a mesh type; and b1-2) performing a wet etching using mixed aqueous solution containing hydrofluoric acid and aqueous hydrogen peroxide.

The step b) may further comprises: b2-1) forming circular metal nano dot array on the upper part of the quantum dot multilayer; and

b2-2) performing a reactive ion etching (RIE) using the metal nano dots as masks.

At this time, a composite nanowire shape in which the nano disc-shaped matrix and nano disc-shaped semiconductors are repeatedly coupled in sequence is fabricated by the etching (wet etching or reactive ion etching) of the step b), and the surface of the nano disc shaped semiconductor is naturally oxidized during or after the etching process.

Quantum dot nanowires whose semiconductor quantum dots are embedded in the matrix are fabricated by the etching of the step b), the size of the semiconductor quantum dots is controlled by the thickness of each semiconductor layers constituting the multilayer, and a light absorption wavelength is controlled by means of the sort of the matrix, the size of the semiconductor quantum dot constituting the quantum dot nanowire or the combination thereof.

The step c) may be the deposition using a CVD or a PVD.

The semiconductor substrate may be a p-type (or an n-type) silicon substrate, the semiconductor doped with the opposite-type impurities is an n-type (or a p-type) silicon, the matrix is silicon oxide or silicon nitride, and the semiconductor layers of the multilayer is silicon.

The present invention provides a solar cell having quantum dot nanowire array fabricated using the fabrication method as described above, comprising:

a lower electrode; a first semiconductor layer formed on the upper part of the lower electrode and doped with n-type (or p-type) impurities; a second semiconductor layer formed over the first semiconductor layer and doped with opposite-type impurities to the first semiconductor layer; an upper electrode formed on an upper part of the semiconductor layer; and a quantum dot nanowire array constituted by a plurality of quantum dot nanowires vertically arranged in the second semiconductor layer to be spaced from each other, wherein the quantum dot nanowire that constitutes the quantum dot nanowire array, whose one end contacts the first semiconductor layer, includes matrix and at least one semiconductor quantum dots surrounded by the matrix.

At this time, the other ends of the quantum dot nanowires are present on the surface of the second semiconductor layer so that the other ends may contact the upper electrode or the other ends of the quantum dot nanowires are present in the second semiconductor layer so that the quantum dot nanowires may be embedded in the second semiconductor layer.

The first semiconductor layer and the second semiconductor layer may have the same semiconductive substances doped with impurities having different nature (p-type or n-type), and the matrix may be semiconductor nitride, semiconductor oxide or a mixture of them. More preferably, the semiconductor nitride or the semiconductor is same as the semiconductor substances constituting the first semiconductor layer and the second semiconductor layer.

The quantum dot nanowire that constitutes the quantum dot nanowire array has two or more semiconductor quantum dots arranged vertically to the quantum dot nanowires, and the semiconductor quantum dots included in the quantum dot nanowires may be fabricated to have the same or different size.

The quantum dot nanowires may be composed of semiconductor quantum dots with diameter of less than 10 nm.

With the solar cell according to the present invention, the wavelength of the light absorption may be controlled by means of the sort of the matrix, the size of the semiconductor quantum dot or the combination thereof.

The first semiconductor layer is a silicon layer, the second semiconductor layer is a silicon layer, the matrix is silicon oxide, silicon nitride or a mixture thereof, and the semiconductor quantum dot is a silicon quantum dot.

### Advantageous Effects

The solar cell according to the present invention includes quantum dot nanowire array with a heterostructure including matrix and semiconductor quantum dots, and p-type and n-type semiconductor and electrodes each contacting the quantum dot nanowires. With the solar cell according to the present invention, the band gap energy of the semiconductor quantum dot can be easily controlled, the semiconductor quantum dots having different sizes are provided in the quantum dot nanowire so that the photoelectric conversion can be taken place in a wide spectrum from visible rays to infrared rays, the quantum dots are embedded in the high density quantum dot nanowire arrays so that light absorption can be maximized, and the quantum dot nanowire contact p-type and n-type semiconductor over a large area, conduction efficiency of electrons and holes can be improved. The fabrication method according to the present invention forms a stacked thin film in which matrix layers and semiconductor layers having the thickness of several nanometers and then etches the stacked thin film, thereby fabricating quantum dot nanowire array formed with semiconductor quantum dots.

Therefore, with the fabrication method according to the present invention, a high efficiency solar cell can be fabricated through a simple and economical process, the wavelength of the absorbing light can be easily controlled by controlling the thickness of the semiconductor layer of the stacked thin film, the sort of matrix, and the contracted diameter of the quantum dot nanowire, etc., and a pair of electron/hole can be generated by absorbing light in a wide spectral region from infrared rays to visible rays.

### DESCRIPTION OF DRAWINGS

The above and other objects, features and advantages of the present invention will become apparent from the following description of preferred embodiments given in conjunction with the accompanying drawings, in which:

FIG. 1 is an example of a process view showing a fabricating method of a solar cell according to the present invention;

FIG. 2 is an example of a process view fabricating a quantum dot nanowire array in a fabricating method of a solar cell according to the present invention;

FIG. 3 is another example of a process view fabricating a quantum dot nanowire array in a fabricating method of a solar cell according to the present invention;

FIG. 4 is an example of a process view showing a step of forming unevenness by RIE in a fabricating method of a solar cell according to the present invention;

FIG. 5 is another example of a process view fabricating a quantum dot nanowire array in a fabricating method of a solar cell according to the present invention; and

FIG. 6 is an example showing a structure of a solar cell according to the present invention.

### DETAILED DESCRIPTION OF MAIN ELEMENTS

| | |
|---|---|
| 110: p-type semiconductor | 120: multilayer |
| 121: matrix layer | 122: semiconductor layer |
| 120′: multilayer with surface unevenness | |
| 130: quantum dot nanowire | 131: matrix |
| 132: semiconductor quantum dot | 140: n-type semiconductor |
| 151, 152: electrodes | |
| 200: metal mesh | 210: circular metal dot |
| 300: nanoporous anodic alumina | |

### BEST MODEL

Hereinafter, a solar cell having quantum dot nanowire array and the fabrication method thereof according to the present invention will be described in detail with reference to the accompanying drawings. The drawings set forth herein are provided so that those skilled in the art can fully understand the present invention. Therefore, the present invention may be embodied in different forms and should not be construed as limited to the embodiments set forth herein. Like reference numerals refer to like elements throughout.

At this time, if there are no specific definitions in technical and scientific terminologies used herein, the terminologies have meanings that are commonly understood by those skilled in the art to which the present invention pertains. In the following description and the accompanying drawings, if it is judged that the specific explanation on the related well-known function or constitution may make the gist of the present invention obscure, the detailed explanation thereof will be omitted.

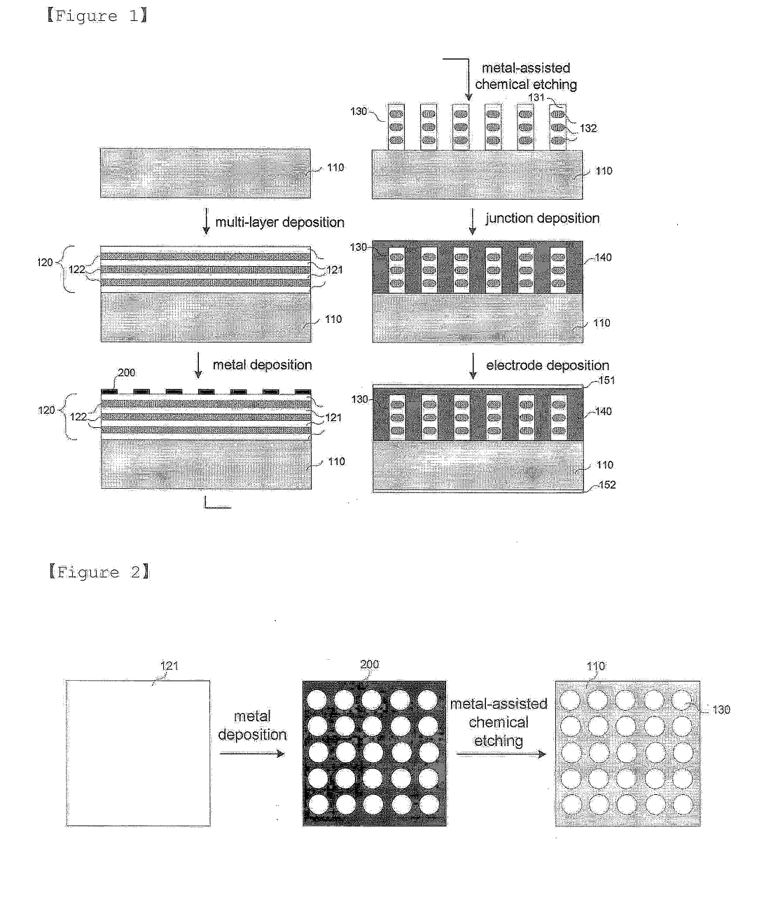

FIG. 1 is an example of a process view showing a fabricating method of a solar cell according to the present invention. Referring to FIG. 1, a multilayer 120 is fabricated on an upper part of a p-type semiconductor layer 110 by alternately depositing a matrix thin film (matrix layer, 121) and a semiconductor thin film (semiconductor layer, 122) using a deposition process, and then quantum dot nanowire 130 array is fabricated in a top-down method that the fabricated multilayer 120 is partially etched in a direction vertical to a surface of the p-type semiconductor layer 110.

At the time of deposition, preferably, the thicknesses of the matrix thin film 121 and the semiconductor thin film 122 are deposited to be nanometer order, respectively, and more preferably, the thickness of the matrix thin film 121 and the semiconductor thin film 122 is deposited to be less than 10 nm, independently from each other.

The matrix thin film 121 is formed of semiconductor oxide, semiconductor nitride, or a mixture thereof. A plurality of matrix thin films 121 constituting the multilayer may have a different substance (semiconductor oxide, semiconductor nitride and a mixture of the semiconductor oxide and semiconductor nitride) and a different thickness for each film.

The quantum dot nanowire 130 according to the present invention is fabricated by partial etching of the multilayer 120, such that it is characterized in that a crystalline or amorphous matrix 131 and a crystalline or amorphous semiconductor 132 constituting the multilayer 120 are mixed with a hetero interface with each other, and has a structure that the crystalline or amorphous semiconductor 132 is embedded in the nanowire in a quantum dot shape.

This means that during or after the etching process for fabricating the quantum dot nanowire 130 array, a surface native oxide of the semiconductor 132 exposed to the surface by the etching is induced to allow the semiconductor constituting the quantum dot nanowire 130 to be embedded in the nanowire in a quantum dot shape.

As described above, the quantum dot nanowire 130 array according to the present invention is characterized by fabricating the quantum dot nanowire 130 array in a top-down method by means of the partial etching of the multilayer 120 rather than by a bottom-up method such as a VLS growth method using noble metal catalysts. Accordingly, the quantum dot nanowire 130 can be formed in a direction vertical to the p-type semiconductor layer, regardless of substances, crystallinity, and crystalline direction of surface, etc. of the p-type semiconductor layer attached with nanowires, wherein a plurality of quantum dot nanowires 130 are regularly arranged, with high density.

The quantum dot nanowire 130 are fabricated by partially etching the multilayer 120 so that the quantum dot nanowire 130 has a structure where two or more embedded quantum dots 132 are arranged vertically to the major axis of the nanowire.

Although semiconductor films 122 having the same thickness are shown in FIG. 1, size of the quantum dots 132 arranged in a major axis direction of the quantum dot nanowire 130 can be controlled to be different by controlling the thickness of the semiconductor films 122 constituting the multilayer 120 to be different.

More specifically, the quantum dot nanowire 130 and the array thereof are fabricated in the top-down method using the etching method, such that the length of the major axis of the quantum dot nanowire 130 can be controlled by controlling the thickness and the number of repetition deposition times of each matrix thin film 121 and semiconductor thin film 122 constituting the multilayer 120, the number of semiconductor quantum dots 132 embedded in the quantum dot nanowire 130 can be controlled by controlling the number of films of the semiconductor thin film 122 constituting the multilayer 120, and the size of the semiconductor quantum dot 132 can be controlled by controlling the thickness of the semiconductor thin film 122 constituting the multilayer 120.

Also, the position of the semiconductor quantum dot 132 within the quantum dot nanowire 130 can be controller by controlling the position of the semiconductor thin film 122 within the multilayer 120.

Also, the major axis of the quantum dot nanowire fabricated by etching the multilayer 120 is preferably controlled to have a length of several nanometers to several hundred nanometers by fabricating the multilayer 120 having the thickness of several nanometers to several hundred nanometers.

In order to fabricate the quantum dot nanowire having a contracted diameter of the order of several to several ten nanometers and the quantum dot nanowire array having a high density, the partial etching is preferably is a metal-assisted chemical etching using metal as catalysts or a reactive ion etching (RIE).

FIG. 1 shows a fabricating method using the metal-assisted chemical etching. The multilayer 120 is fabricated by repeatedly depositing the matrix thin film 121 and the semiconductor thin film 122 so that the layer thickness thereof becomes nanometer order, respectively, and then a catalyst metal which is Ag, Au or a transition metal, is deposited on an upper part of the multilayer 120 in a mesh type. The contracted diameter of the quantum dot nanowire 130 to be fabricated is determined according to the size of empty cavity of the mesh-type catalyst metal 200. Preferably, the shape of catalyst metal is a mesh type where circular cavities having a diameter of the order of several to several ten nanometers are regularly arranged to be spaced from each other.

After the mesh type catalyst metal 200 performing catalysis on the etching is formed, the quantum dot nanowire 130 array whose one ends are contacted/fixed to the p-type semiconductor layer 110 and are regularly and densely arranged in a uniform size are fabricated.

Thereafter, an n-type semiconductor doped with opposite-type impurities is deposited on the p-type semiconductor layer 110.

At the time of the deposition, all empty spaces formed by the partial etching of the multilayer 120 on the upper part of the p-type semiconductor layer are filled with an n-type semiconductor 140, and preferably, the quantum dot nanowire 130 array are completely covered therewith, to deposit them so that the n-type semiconductor 140 remains only on the surface.

This is to improve external extraction efficiency by allowing electrons-holes generated from the semiconductor quantum dots 130 to be smoothly isolated and moved by absorbing light.

Thereafter, electrodes are formed on the lower part of the p-type semiconductor layer 110 and the surface of the n-type semiconductor 140, respectively, thereby fabricating a solar cell according to the present invention.

FIG. 2 is a plan view showing a step of a mesh type catalyst metal and an etching step in the fabricating method of FIG. 1. After the mesh type catalyst metal 200 in which circular cavities having a diameter of order of several to several tens of nanometer are regularly arranged to be spaced from each other is formed on the upper part of a matrix layer 121 formed on the uppermost part of the multilayer 120, a wet chemical etching using the metal 200 as a catalyst is performed to fabricate quantum dot nanowire array having a regularly dense structure where they are arranged vertically to the p-type semiconductor layer 110.

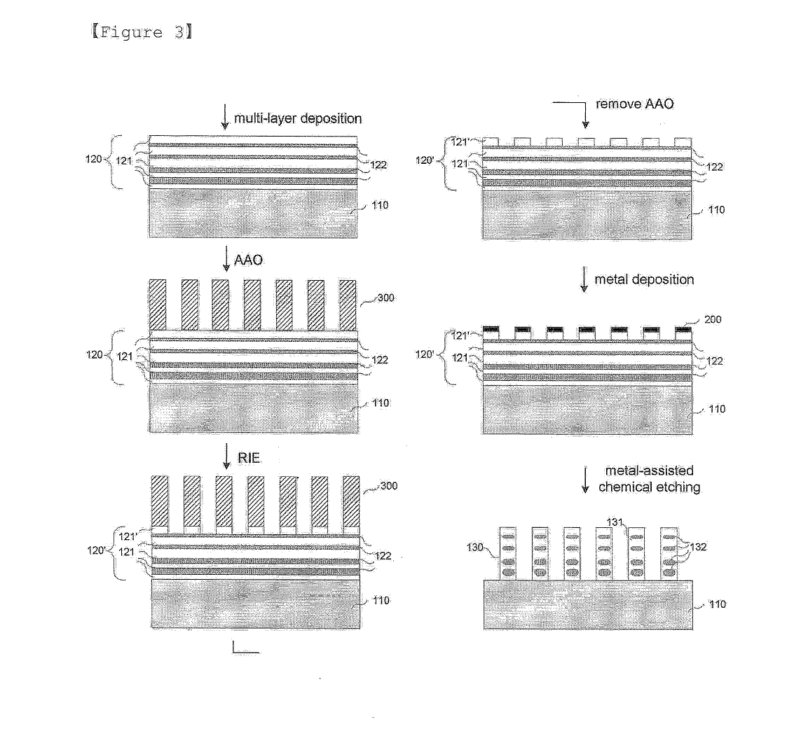

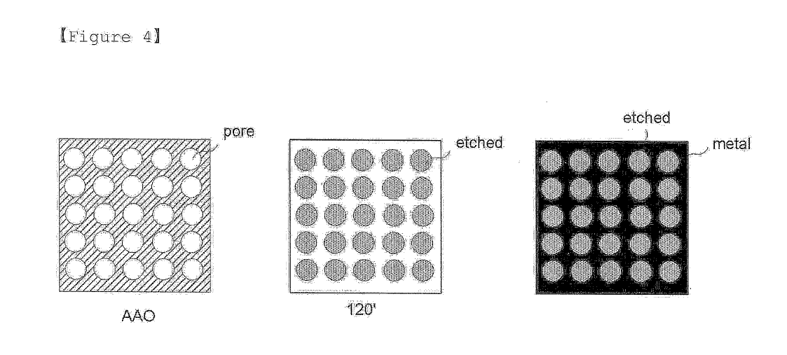

FIG. 3 is a process cross-sectional view more precisely showing a step of fabricating quantum dot nanowire array by performing a chemical etching using a catalyst metal in the fabrication method according to the present invention. FIG. 3 shows a case where the semiconductor thin films 12 are deposited to have different thickness in order to fabricate quantum dot nanowires in which several sizes of semiconductor quantum dots are embeddingly arranged in a vertical direction of the nanowire.

In order to fabricate the quantum dot nanowire 130 at high density so that it has a high specific surface area and to fabricate the contracted diameter of the quantum dot nanowire 130 in the order of several to several tens of nanometer, the mesh type catalyst metal 200 is preferably fabricated using nanoporous anodic aluminum oxide (AAO) 300 as a mask.

The nanoporous anodic alumina oxide, which is anodic aluminum oxide formed with penetration porosities, can be fabricated by anodizing aluminum using sulfuric acid, oxalic acid or phosphoric acid as an electrolyte. The more detailed fabrication method of the nanoporous anodic alumina oxide is disclosed in the present applicant's thesis (W. Lee et al. Nature Nanotech. 3, 402 (2008)) and reference therein.

More specifically, as shown in FIGS. 3 and 4, surface unevenness is formed on the surface of the multilayer 120 by performing partial reactive ion etching (RIE) on the multilayer 120 using the nanoporous anodic alumina oxide 300 as a mask.

Therefore, the multilayer 120 is etched at a predetermined depth (etched of FIG. 4) in a shape of the porosity portion (pore of FIG. 4) of the nanoporous anodic alumina oxide, thereby forming the surface unevenness.

Thereafter, the catalyst metal is deposited on the upper part of the multilayer 120′ on which the surface unevenness is formed. At the time of the deposition, the catalyst metal is selectively deposited on a convex region (region not etched by the RIE) by a surface step of the multilayer 120′, thereby fabricating mesh type metals 200 in which cavities having similar size and arrangement with the nanoporous anodic alumina oxide are formed.

The metal 200 performing catalysis at the time of chemical etching is preferably Ag, Au or a catalyst metal which is a transition metal, wherein the transition metal is preferably Fe or Ni.

In the wet etching using the metal catalyst, etching solution is preferably a mixed aqueous solution mixed with hydrofluoric acid and aqueous hydrogen peroxide.

Preferably, the etching solution is a mixed solution having the volume ratio of hydrofluoric acid:aqueous hydrogen peroxide:water being 1:0.3˜0.7:3˜4. This is the substances and ratio that can efficiently etch the semiconductor thin film 122 and the matrix thin film 121 constituting the multilayer 120 under the metal catalyst, and the condition for fabricating the quantum dot nanowire 130 having the even surface irrespective of the length thereof.

As the wet etching is processed, the quantum dot nanowire shape in which nano disc shaped matrix and nanodisc-shaped semiconductor are repeatedly coupled in sequence is fabricated, wherein the surface of the nanodisc shaped semiconductor reacts to oxygen (aqueous hydrogen peroxide, water) contained in the etching solution so that the surface thereof is naturally oxidized. Thereby, the surface of the semiconductor which was in a nanodisc shape is naturally oxidized by the etching liquid, consequently having a structure that the semiconductor is embedded inside the quantum dot nanowire in a quantum dot shape.

Through the chemical etching using the metal mesh 200 and the metal catalyst using the nanoporous anodic alumina oxide (AAO), the contracted diameter of the quantum dot nanowire can be fabricated having a very fine nanowire of 5 nm to 25 nm at high density of about 2×10¹⁰ to 3×10¹⁰/cm² (see the present applicant's thesis Nano Lett. 8, 3046-3051, 2008).

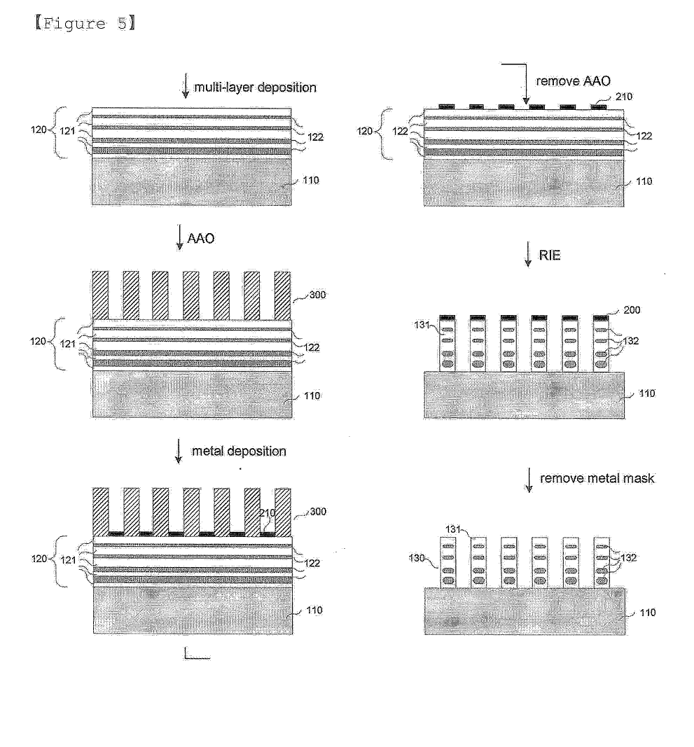

FIG. 5 is a process cross-sectional view showing a step of fabricating a quantum dot nanowire array by performing a reactive ion etching in the fabrication method according to the present invention.

After a multilayer 120 is formed through a deposition process, the quantum dot nanowire array can be fabricated by using the chemical wet etching using the aforementioned metal catalyst, and the quantum dot nanowire array can be fabricated by using the nanoporous anodic aluminum oxide (AAO) and the reactive ion etching (RIE) as shown in FIG. 5.

As shown in FIG. 5, metal is deposited on the upper part of the multilayer 120 using the nanoporous anodic aluminum oxide (AAO) 300 as a mask. At this time, the metal is deposited on the upper part of the multilayer 120 having the size and arrangement similar to those of the porosities of the nanoporous anodic alumina oxide. The quantum dot nanowire 130 array is fabricated by performing a reactive ion etching (RIE) vertically on the p-type semiconductor layer 110, using a circular metal dot (circular disc shaped metal in a nano size) 210 fabricated through the metal deposition process as a mask.

At this time, when being exposed to air after the reactive ion etching is performed, the surface of the semiconductor is naturally oxidized by oxygen, thereby having a semiconductor quantum dot shape where the semiconductor is embedded inside the quantum dot nanowire 130 in the same manner as the chemical wet etching.

The method shown in FIG. 5 can fabricate fine nanowires having the thickness of several nanometers at high density, in spite of somewhat long process time compared to the chemical wet etching. In the RIE process, SF₆/O₂ plasma (40 sccm, 10 mTorr and 200 W) is preferably used and an advantage is obtained in that the length of the quantum dot nanowire can be controlled by adjusting the time of RIE.

The following can be obtained through the fabrication method according to the present invention described with reference to FIGS. 1 to 5.

After the matrix layer and semiconductor layer having the thickness of several nanometers are deposited sequentially on the upper part of the p-type semiconductor or the n-type semiconductor of p-n junctions of the optical device, fine quantum dot nanowire array having density is fabricated in a top-down method through a chemical wet etching using the nanoporous anodic alumina oxide or the catalyst metal; or a dry etching using the nanoporous anodic alumina oxide or the reactive ion etching.

The surface of the semiconductor constituting the quantum dot nanowire is naturally oxidized by being subject to etching agent during the etching or oxygen atmosphere after the etching is completed, thereby forming a structure that is embedded inside the quantum dot nanowire in a semiconductor quantum dot shape.

The empty space between quantum dot nanowires generated by being etched is deposited with the semiconductor substances doped with opposite-type impurities to form the p-n junction having a high movement efficiency of electrons/holes.

The thickness of the semiconductor thin film and the sort of substances of matrix thin film are controlled during the deposition process of the multilayer to finally control the band gap energy of the semiconductor quantum dot inside the quantum dot nanowire.

The semiconductor thin films having different thickness are deposited alternately with the matrix thin film during the deposition process of the multilayer to have various ranges of band gap energy, making it possible to absorb light in a wide wavelength region from infrared rays to visible rays.

The multilayer may be deposited through a general semiconductor deposition process using a PVD or a CVD. The deposition of the semiconductor materials doped with the opposite-type impurities may be performed through a general semiconductor process using a PVD or a CVD, preferably, the deposition using the CVD.

The electrodes 151 and 152 are fabricated using a general printing method such as a screen printing using conductive metal paste and a stencil printing or a deposition method using a PVD/CVD.

The fabrication method according to the present invention can easily control the light absorption wavelength (band gap of semiconductor quantum dot) by means of the sort of matrix, the size of semiconductor quantum dot constituting the quantum dot nanowire or the combination thereof, and further can easily and rapidly fabricate a low dimensional nanostructure shaped photoactive layer in a top-down method with a low cost.

The fabrication method according to the present invention can fabricate the solar cell using semiconductive substances generating a pair of electron-hole absorbing light as the semiconductor quantum dot, semiconductive substances doped with p-type impurities as the p-type semiconductor, semiconductive substances doped with n-type impurities as the n-type semiconductor, and nitride or oxide of the semiconductive substances as the matrix. However, in order to efficiently fabricate the solar cell using the present invention, preferably, the semiconductor substrate is a p-type silicon substrate, the semiconductor doped with the opposite-type impurities is a n-type silicon, the matrix is silicon oxide or silicon nitride, and the semiconductor of the multilayer is silicon.

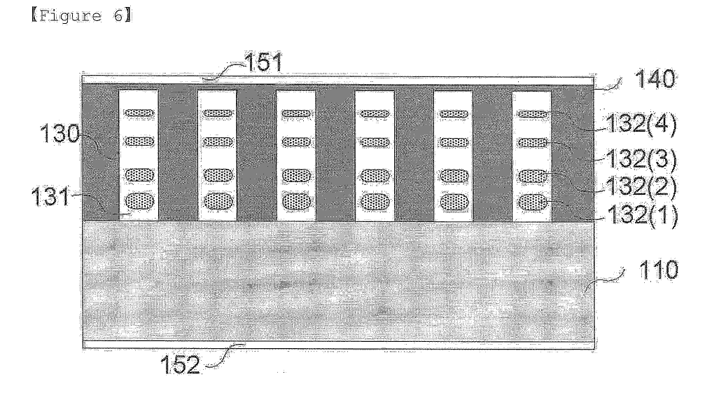

FIG. 6 shows a cross-section structure of a solar cell fabricated according to the fabrication method of the present invention. Referring to FIG. 6, the solar cell includes a lower electrode 152; a first semiconductor layer formed on the lower electrode and doped with n-type or p-type impurities; a second semiconductor layer 140 formed over the first semiconductor layer and doped with impurities opposite-type to the first semiconductor layer 110; an upper electrode 151 formed on the semiconductor layer 140; and quantum dot nanowire 130 array vertically arranged in the second semiconductor layer 140 to be spaced from each other, wherein the quantum dot nanowires 130, whose one ends contact the first semiconductor layer 110, include matrix 131 and at least one semiconductor quantum dots 132 surrounded by the matrix.

At this time, the other ends of the quantum dot nanowires 130 are present on the surface of the second semiconductor layer 140 so that the other ends may contact the upper electrode 151 or the other ends of the quantum dot nanowires 130 are present in the second semiconductor layer 140 so that the quantum dot nanowires 130 may be embedded in the second semiconductor layer 140.

The matrix 131 is semiconductor nitride, semiconductor oxide or a mixture thereof.

Preferably, the first semiconductor layer 110 and the second semiconductor layer 140 have the same semiconductive substances doped with impurities opposite-type to each other, and the matrix is nitride of semiconductive substances of the first or second semiconductor layers 110 and 140, oxide of semiconductive substances of the first or second semiconductor layers 110 and 140, or a mixture thereof.

In the quantum dot nanowire 130, two or more semiconductor quantum dots 132 are arranged vertically to the quantum dot nanowire 130, wherein the semiconductor quantum dots 132 provided in the quantum dot nanowire 130 have different sizes. At this time, the diameter of the semiconductor quantum dot provided in the quantum dot nanowire is 1 nm to 10 nm, the contracted diameter of the quantum dot nanowire is 5 nm to 10 nm, and the density of the quantum dot nanowire is 2×10¹⁰ to 3×10¹⁰/cm².

With the solar cell according to the present invention, the size of the semiconductor quantum dot and the sort of matrix are controlled, making it possible to easily control the band gap energy of the semiconductor quantum dot, the semiconductor quantum dots having different sizes are provided in the quantum dot nanowire, making it possible to perform the photoelectric conversion in the wide spectrum from visible rays to infrared rays, the photoactive part where a photoelectric conversion occurs is in a low dimensional nanostructure shape of high density quantum dot nanowire array, making it possible to maximize light absorption, the quantum dot nanowire contact p-type and n-type semiconductor over a wide area, making it possible to improve conduction efficiency of electrons and holes.

More specifically, the solar cell according to the present invention performs a photoelectric conversion on all wavelength regions of the solar cell by controlling the band gap energy of the silicon quantum dot to maximize the internal light generating efficiency, constitutes the photoactive part in a low dimensional nanostructure shape having a high specific surface area to maximize the light absorption and photoelectric conversion efficiency, and has quantum dot nanowires each having a structure being surrounded by the n-type semiconductor and contacting the p-type semiconductor to improve conduction efficiency of electrons-holes generated by the light.

Preferably, the first semiconductor layer is a p-type silicon layer, the n-type semiconductor layer is an n-type silicon layer, the matrix is silicon oxide, silicon nitride or a mixture thereof, and the semiconductor quantum dot is a silicon quantum dot.

Those skilled in the art will appreciate that the conceptions and specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

1. A fabrication method of a solar cell having quantum dot nanowire array comprising:
a) fabricating a multilayer by repeatedly stacking matrix layers formed of semiconductor nitride or semiconductor oxide, and semiconductor layers on an upper part of a semiconductor substrate doped with p-type or n-type impurities;
b) fabricating a quantum dot nanowire array constituted by a plurality of quantum dot nanowires whose one ends are fixed on the semiconductor substrate and are spaced from each other to be vertically arranged by partially etching the multilayer vertically to the semiconductor substrate and;
c) depositing a semiconductor doped with the opposite-type impurities to impurities of the semiconductor substrate on the upper part of the semiconductor substrate formed with the quantum dot nanowire array and filling at least empty spaces between the other ends of the quantum dot nanowires and the semiconductor substrate with the semiconductor doped with opposite-type impurities; and
d) forming a lower electrode on a lower part of the semiconductor substrate, and forming a upper electrode on a upper part surface formed with the quantum dot nanowire array and semiconductor surface doped with the opposite-type impurities or on an upper part of semiconductor surface doped with the opposite-type impurities so that the upper electrode corresponds to the lower electrode.

2. The fabrication method of the solar cell having quantum dot nanowire array according to claim 1, wherein the multilayer of a) step is fabricated through a deposition process using PVD or CVD, and the thickness of the semiconductor layers constituting the multilayer are different.

3. The fabrication method of the solar cell having quantum dot nanowire array according to claim 1 or 2, wherein the semiconductor layer and the matrix layer constituting the multilayer have the thickness of less than 10 nm, independently from each other.

4. The fabrication method of the solar cell having quantum dot nanowire array according to claim 1, wherein the step b) further comprises:
b1-1) depositing Ag, Au or a catalyst metal that is a transition metal on the upper part of the multilayer in a mesh type; and b1-2) performing a wet etching using mixed aqueous solution containing hydrofluoric acid and hydrogen peroxide.

5. The fabrication method of the solar cell having quantum dot nanowire array according to claim 1, wherein the step b) further comprises:
b2-1) forming circular metal nano dot array on the upper part of the multilayer; and
b2-2) performing a reactive ion etching (RIE) using the metal nano dots as masks.

6. The fabrication method of the solar cell having quantum dot nanowire array according to claim 4 or 5, wherein quantum dot nanowires whose semiconductor quantum dots are embedded in the matrix are fabricated by the etching of the step b), and the size of the semiconductor quantum dots is controlled by the thickness of each semiconductor layers constituting the multilayer.

7. The fabrication method of the solar cell having quantum dot nanowire array according to claim 6, wherein a light absorption wavelength is controlled by means of the sort of the matrix, the size of the semiconductor quantum dot constituting the quantum dot nanowire or the combination thereof.

8. The fabrication method of the solar cell having quantum dot nanowire array according to claim 3, wherein the step c) is the deposition using a CVD or a PVD.

9. The fabrication method of the solar cell having quantum dot nanowire array according to claim 1, 2, 4, 5 or 7, wherein the semiconductor substrate is a p-type or an n-type silicon substrate, the semiconductor doped with the opposite-type impurities is an n-type or a p-type silicon, the matrix is silicon oxide or silicon nitride, and the semiconductor layers of the multilayer is silicon layers.

10. A solar cell having quantum dot nanowire array fabricated using a fabrication method according to any one of claim 1, 2, 4, 5, 7 or 8, comprising:
a lower electrode;
a first semiconductor layer formed on an upper part of the lower electrode and doped with n-type or p-type impurities;
a second semiconductor layer formed over the first semiconductor layer and doped with impurities opposite-type to the first semiconductor layer;
an upper electrode formed on an upper part of the semiconductor layer; and
a quantum dot nanowire array constituted by a plurality of quantum dot nanowires vertically arranged in the second semiconductor layer to be spaced from each other,
wherein the quantum dot nanowire that constitutes the quantum dot nanowire array, whose one end contacts the first semiconductor layer, includes matrix and at least one semiconductor quantum dots surrounded by the matrix.

11. The solar cell having quantum dot nanowire array according to claim 10, wherein the matrix is semiconductor nitride, semiconductor oxide or a mixture thereof.

12. The solar cell having quantum dot nanowire array according to claim 10, wherein the quantum dot nanowire that constitutes the quantum dot nanowire array has two or more semiconductor quantum dots arranged vertically to the quantum dot nanowires.

13. The solar cell having quantum dot nanowire array according to claim 12, wherein the quantum dot nanowire is configured of the semiconductor quantum dots having different sizes.

14. The solar cell having quantum dot nanowire array according to claim 10, 12 or 13, wherein the diameter of the semiconductor quantum dot in the quantum dot nanowire is less than 10 nm.

15. The solar cell having quantum dot nanowire array according to any one of claim 10, 11, 12, or 13, wherein a light absorption wavelength is controlled by means of the sort of the matrix, the size of the semiconductor quantum dot or the combination thereof.

16. The solar cell having quantum dot nanowire array according to claim 15, wherein the first semiconductor layer is a p-type silicon layer, the second semiconductor layer is an n-type silicon layer, the matrix is silicon oxide, silicon nitride or a mixture thereof, and the semiconductor quantum dot is a silicon quantum dot.
